(19) United States
(12) Patent Application Publication
(10) Pub. No.: US 2025/0081679 A1
(43) Pub. Date: Mar. 6, 2025

(54) INVERTED LED FILAMENT AND LED LIGHT BULB

(71) Applicant: XIULI LIU, Zhumadian (CN)

(72) Inventor: XIULI LIU, Zhumadian (CN)

(21) Appl. No.: 18/240,513

(22) Filed: Aug. 31, 2023

(51) Int. Cl. H01L 33/44; F21K 9/235; F21K 9/90; H01L 27/15

(52) U.S. Cl. CPC H10H 20/84; F21K 9/235; F21K 9/90; H10H 29/10

(57) ABSTRACT

The present disclosure discloses an inverted LED filament, which includes a circuit board provided with a conductive layer thereon; multiple inverted LED light emitting elements, where the circuit board is provided with a strip-shaped portion, the inverted LED light emitting elements are arranged on the strip-shaped portion, and the inverted LED light emitting elements are all electrically connected to the conductive layer; a pad assembly provided on the circuit board and located at the same side end of the strip-shaped portion, being electrically connected to the conductive layer, and being connected to an external pin. By providing the inverted LED light emitting elements on the strip-shaped portion of the circuit board, and the pad assembly is located at the same side end of the strip-shaped portion, this structure allows the pad assembly to prevent light generated by the inverted LED light emitting elements from being shielded by the pin.

### TECHNICAL FIELD

The present disclosure relates to the field of lighting technologies, and in particular, to an inverted LED filament and a LED light bulb.

### BACKGROUND

With the development of lighting technology, traditional incandescent lamps (tungsten filament lamps) have gradually been phased out due to their high energy consumption and short service life. Instead, LED light bulbs are similar in shape to traditional incandescent lamps and adopt the existing traditional screw and socket connection method, which conforms to people's habits of using light bulbs.

However, referring to FIG. 1, in existing technology, the LED light bulb includes a connection base 100, LED filament 110, and pin 120. The LED filament 110 is a structure with two ends connected, this results in that the pin 120 is needed to achieve that two ends of the LED filament 110 are electrically connected to the base 100 when the LED filament 110 is vertically set. In this structure, the pin 120 will shield one side of the LED filament 110, as the LED filament 110 can provide omnidirectional illumination; thus, light generated by LED filament 110 will be shielded by the pin 120, and cause a local dark area, thereby reducing an illumination angle of LED filament 110, uneven illumination brightness, and affecting a lighting effect.

### SUMMARY

The present disclosure aims to solve at least one of the technical problems existing in the existing technology. Thus, the present disclosure provides an inverted LED filament and a LED light bulb, which can prevent the light generated by the inverted LED light emitting element from being shielded by the pin, rendering the lighting brightness uniform, and improving the lighting effect.

According to an embodiment of a first aspect of the present disclosure, an inverted LED filament includes a circuit board provided with a conductive layer thereon; multiple inverted LED light emitting elements, where the circuit board is provided with a strip-shaped portion, the inverted LED light emitting elements are arranged on the strip-shaped portion, and the inverted LED light emitting elements are all electrically connected to the conductive layer; a pad assembly provided on the circuit board and located at the same side end of the strip-shaped portion, being electrically connected to the conductive layer, and being connected to a connection base of an external LED light bulb.

According to an embodiment of the present disclosure, the inverted LED filament has at least the following beneficial effects: by providing the inverted LED light emitting elements on the strip-shaped portion of the circuit board, and the pad assembly is located at the same side end of the strip-shaped portion. This structure allows the pad assembly to prevent light generated by the inverted LED light emitting element from being shielded by the pin when the pad assembly is connected to the connection base of the external LED light bulb through an external pin, rendering the lighting brightness more uniform, and improving the lighting effect.

According to some embodiments of the present disclosure, a first electrode and a second electrode are provided on the same side wall of the inverted LED light emitting elements, and the conductive layer includes at least two circuit parts with a gap between the circuit parts, and the first electrode and the second electrode are respectively connected to two different circuit parts.

According to some embodiments of the present disclosure, the inverted LED filament further includes a fluorescent adhesive layer provided on the circuit board, where the fluorescent adhesive layer surrounds the strip-shaped portion and is covered on the inverted LED light emitting element.

According to some embodiments of the present disclosure, the inverted LED filament further includes a protective element provided on the circuit board and surrounding a connection position of the pad assembly and the external pin.

According to some embodiments of the present disclosure, the circuit board is made of a transparent material.

According to some embodiments of the present disclosure, the inverted LED filament further includes a rectification unit provided on the circuit board, the multiple inverted LED light emitting elements are connected in series, parallel, or series parallel to form a light emitting circuit, an input end of the rectification unit is electrically connected to the pad assembly through the conductive layer, and an output end of the rectification unit is electrically connected to the light emitting circuit through the conductive layer.

According to some embodiments of the present disclosure, the rectification unit includes a bridge rectifier, an input end of the bridge rectifier is electrically connected to the pad assembly, and an output end of the bridge rectifier is electrically connected to the light emitting circuit.

According to some embodiments of the present disclosure, at least two strip-shaped portions are provided on the circuit board.

A LED light bulb according to a second embodiment of the present disclosure includes: the inverted LED filament, the pin, a connection base, and a light transmission cover. The pad assembly is connected to the connection base through the pin, and the light transmission cover is connected to the connection base to form a protective chamber accommodating the inverted LED filament. The connection base can be connected to an external lamp holder.

According to the embodiment of the present disclosure, the LED light bulb has at least the following beneficial effects: a protective chamber accommodating the LED filament is formed by connecting the light transmission cover and the connecting base, this structure is beneficial for preventing an external object from colliding with the LED filament and avoiding filament damage. In addition, the pad assembly of the strip-shaped circuit board can be connected to the connection base through the pin, and the pad assembly is located at the same side end of the strip-shaped portion, which can prevent the light generated by the inverted LED light emitting elements on the strip-shaped portion from being shielded by the pin, which is conducive to rendering the lighting brightness more uniform and improving the lighting effect.

According to some embodiments of the present disclosure, a threaded part is provided on the connection base for connecting with the external lamp holder.

The additional aspects and advantages of the present disclosure will be partially provided in the following description, and some will become apparent from the following description, or learned through the practice of the present disclosure.

### BRIEF DESCRIPTION OF DRAWINGS

The above and/or additional aspects and advantages of the present disclosure will become apparent and easy to understand from the description of the embodiments in combination with the drawings.

FIG. 1 is a schematic diagram of a traditional LED light bulb.

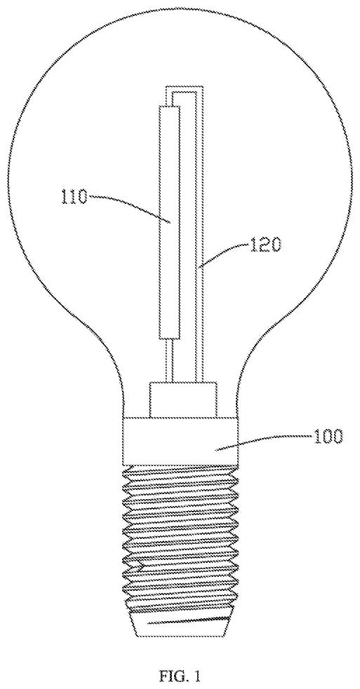

FIG. 2 is a schematic diagram of a LED light bulb in an embodiment of the present disclosure.

FIG. 3 is a schematic diagram of a LED filament in an embodiment of the present disclosure.

FIG. 4 is a cross-sectional view of the LED filament in an embodiment of the present disclosure.

FIG. 5 is an enlarged schematic diagram at position A in FIG. 4.

FIG. 6 is a structural diagram of an inverted LED light emitting element in an embodiment of the present disclosure.

FIG. 7 is a schematic diagram of the LED filament in another embodiment of the present disclosure.

FIG. 8 is a circuit diagram of the LED filament in another embodiment of the present disclosure.

FIG. 9 is a schematic diagram of the LED filament in yet another embodiment of the present disclosure.

### DETAILED DESCRIPTION

The following describes in detail the embodiments of the present disclosure, and examples of the embodiments are shown in the drawings, where the same or similar reference number throughout represent the same or similar components or components with the same or similar functions. The embodiments described below with reference to the drawings are exemplary and are only intended to explain the present disclosure and cannot be understood as limitations to the present disclosure.

In the description of the present disclosure, it should be understood that when it involves a directional description, such as a directional or a positional relationship indicated as up, down, front, back, left, right, are based on a directional or positional relationship shown in the drawings, it is only for the convenience of describing the present disclosure and simplifying the description, rather than indicating or implying that the device or component referred to must have a specific direction, be constructed and operated in a specific direction. Thus, it cannot be understood as a limitation on the present disclosure.

In the description of the present disclosure, if there is a description of first and second are only for a purpose of distinguishing technical feature, and cannot be understood as indicating or implying a relative importance, implying the number of indicated technical feature, or implying an order relationship of indicated technical feature.

In the description of the present disclosure, unless otherwise specified, the words “providing, installation, connection, etc.” should be understood in a broad sense. Technical personnel in the field can reasonably determine a specific meaning of the above words in the present disclosure based on a specific content of the technical solution.

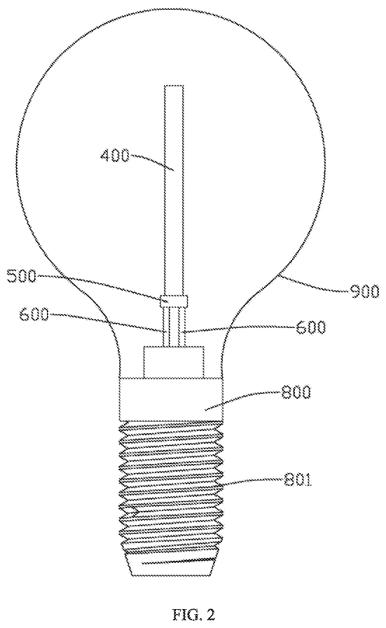

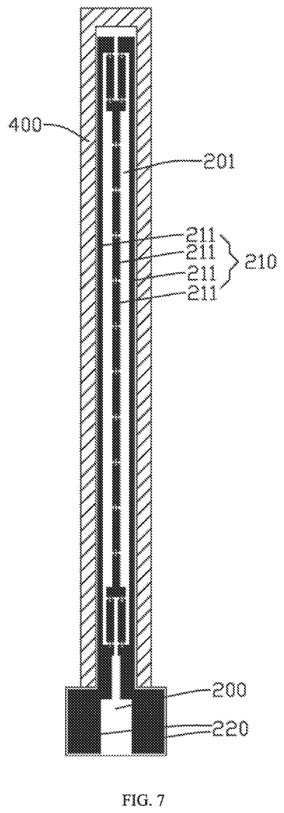

As shown in FIGS. 2 to 4, 7, and 9, an inverted LED filament according to an embodiment of the present disclosure includes a circuit board 200 provided with a conductive layer 210 thereon; multiple inverted LED light emitting elements 310, the circuit board 200 is provided with a strip-shaped portion 201, the inverted LED light emitting elements 310 are arranged on the strip-shaped portion 201, the inverted LED light emitting elements 310 are all electrically connected to the conductive layer 210; a pad assembly 220 provided on the circuit board 200 and located at the same side end of the strip-shaped portion 201. The pad assembly 220 is electrically connected to the conductive layer 210 and can be connected to an external pin 600.

By providing the inverted LED light emitting element 310 on the strip-shaped portion 201 of the circuit board 200, and the pad assembly 220 is located at the same side end of the strip-shaped portion 201, this structure allows pad assembly 220 to prevent light generated by the inverted LED light emitting element 310 from being shielded by the pin 600 when the pad assembly 220 is connected to a connection base 800 of the external LED light bulb through an external pin 600, renders the lighting brightness more uniform and improves a lighting effect.

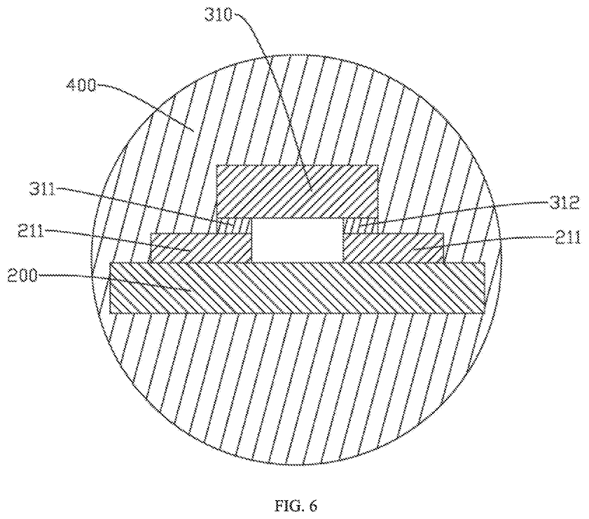

Referring to FIG. 6, in some embodiments of the present disclosure, a first electrode 311 and a second electrode 312 are provided on the same side wall of the inverted LED light emitting elements 310. The conductive layer 210 includes at least two circuit parts 211 with a gap between them. The first electrode 311 and the second electrode 312 are respectively connected to two different circuit parts 211.

When using the inverted LED light emitting element 310, such as an inverted LED chip, the first electrode 311 and second electrode 312 of the inverted LED light emitting element 310 are located at the same side wall. Therefore, when the inverted LED light emitting element is welded to the conductive layer 210, the first electrode 311 and second electrode 312 can be directly welded to the circuit part 211 without a wire connection, which can avoid wire breakage and improve reliability.

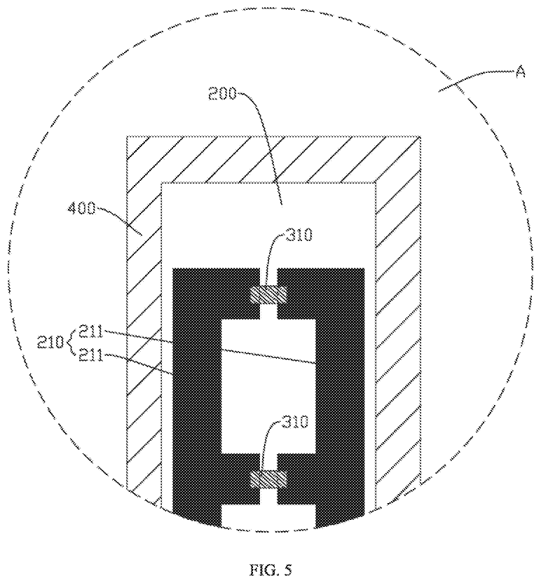

Referring to FIGS. 2 to 7 and 9, in some embodiments of the present disclosure, the inverted LED filament further includes a fluorescent adhesive layer 400 provided on the circuit board 200, the fluorescent adhesive layer 400 surrounds the strip-shaped portion 201 and is covered on the inverted LED light emitting element 310.

By providing the fluorescent adhesive layer 400 that is covered on the inverted LED light emitting element 310, the inverted LED light emitting element 310 can be protected from damage. At the same time, by providing fluorescent adhesive layers 400 with different color, it can change the lighting color, and it is conducive to meeting usage needs and improving the lighting effect.

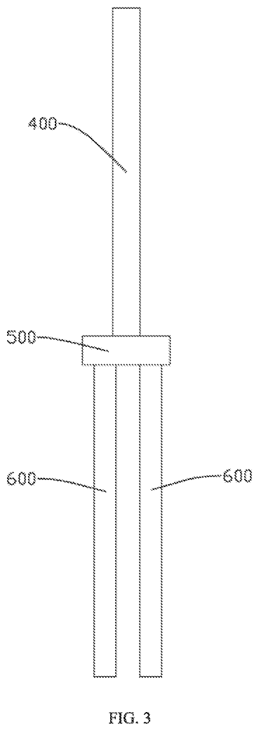

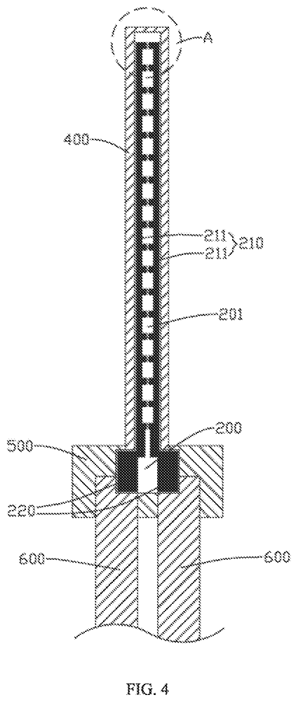

Referring to FIGS. 3 and 4, in some embodiments of the present disclosure, the inverted LED filament further includes a protective element 500 provided on the circuit board 200 and surrounding a connection position of the pad assembly 220 and the pin 600.

After welding the pad assembly 220 with the external pin 600, the protective element 500 is provided to surround the connection position of the pad assembly 220 and the pin 600, which is beneficial for protecting the pad assembly 220, avoiding the pad assembly 220 to be separated from and the pin 600, and improving a reliability of the structure.

In some embodiments of the present disclosure, the circuit board 200 is made of a transparent material. By doing so, the light generated by the inverted LED light emitting element 310 can be emitted from the back of the circuit board 200 through the circuit board 200, which is conducive to achieving a comprehensive illumination effect. The transparent material can be a material such as aluminum oxide ceramics that can transmit light.

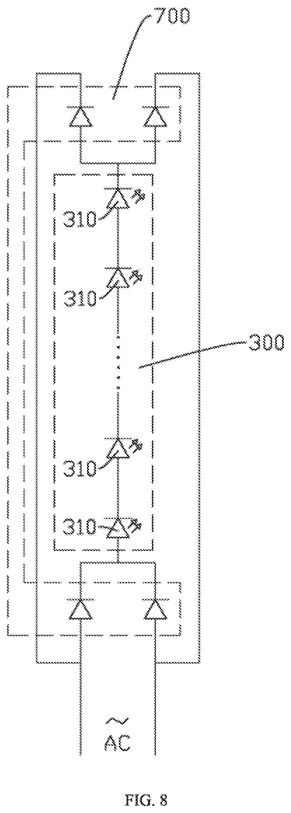

Referring to FIG. 8, in some embodiments of the present disclosure, the inverted LED filament further includes a rectification unit 700 provided on the circuit board 200, the multiple inverted LED light emitting elements 310 are connected in series, parallel, or series parallel to form a light emitting circuit 300. An input end of the rectification unit 700 is electrically connected to the pad assembly 220 through the conductive layer 210, and an output end of the rectification unit 700 is electrically connected to the light emitting circuit 300 through the conductive layer 210.

Due to a unidirectional conduction characteristic of the inverted LED light emitting element 310, a direct current is needed to be provided for a normal operation. When an external power supply inputs alternating current, the rectification unit 700 converts the alternating current into direct current and transmits it to the inverted LED light emitting element 310, enabling the inverted LED light emitting element 310 to work normally. This enables the LED filament to be used in different usage environments when the external power supply inputs alternating current.

Referring to FIG. 8, in some embodiments of the present disclosure, the rectification unit 700 includes a bridge rectifier, an input end of the bridge rectifier is electrically connected to the pad assembly 220, and an output end of the bridge rectifier is electrically connected to the light emitting circuit 300.

The input AC power is rectified through the bridge rectifier, which has a simple structure and is easy to implement. The bridge rectifier can be composed of four ordinary diodes, or it can be composed of a light emitting diode.

The rectification unit 700 can also be an apparatus or a circuit that includes a switching power supply chip, an AC to DC chip, etc., and can achieve rectification effects.

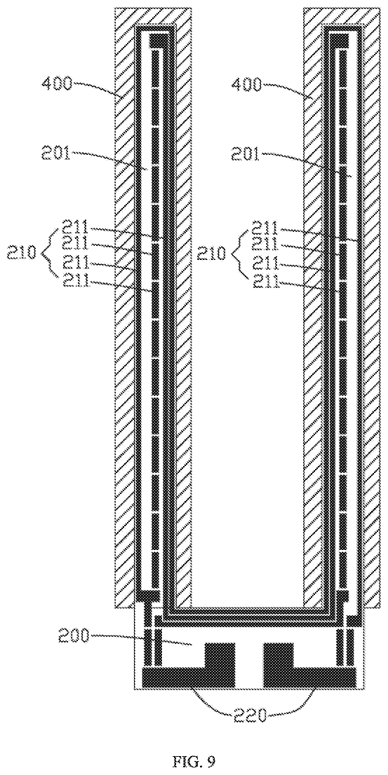

Referring to FIG. 9, in some embodiments of the present disclosure, at least two strip-shaped portions 201 are provided on the circuit board 200.

By providing multiple strip-shaped portions 201, a larger number of inverted LED light emitting elements 310 can be provided, thereby improving an overall lighting brightness and meeting usage needs. Due to a strip-shaped light emitting part formed by the strip-shaped portion 201 in combination with the inverted LED light emitting element 310 is an omnidirectional light source, an obstruction between the strip-shaped portions 201 will not cause that the overall lighting effect has a dark area.

Referring to FIG. 2, a LED light bulb according to a second embodiment of the present disclosure includes the inverted LED filament, the pin 600, a connection base 800, and a light transmission cover 900. The pad assembly 220 is connected to the connection base 800 through the pin 600, and the light transmission cover 900 is connected to the connection base 800 to form a protective chamber accommodating the circuit board 200.

The protective chamber for accommodating the LED filament is formed by connecting the light transmission cover 900 with the connection base 800, this structure is beneficial for preventing an external object from colliding with the LED filament and avoiding filament damage. In addition, the pad assembly 220 of the strip-shaped circuit board can be connected to the connection base 800 through the pin 600, and the pad assembly 220 is located at the same side end of the strip-shaped portion 201, which can prevent the light generated by the inverted LED light emitting element 310 on the strip-shaped portion 201 from being shielded by the pin 600, which is conducive to rendering the lighting brightness more uniform and improving the lighting effect.

Referring to FIG. 2, in some embodiments of the present disclosure, a threaded part 801 is provided on the connection base 800 for connecting with an external lamp holder.

The connection base 800 is connected to the external lamp holder through the threaded part 801, which is convenient for disassembly and assembly, has a simple structure, and conforms to the usage habits of traditional light bulbs, rendering it is more convenient when in use. The connection base 800 can also be detachably connected to the external lamp holder through a common clamping structure.

The various technical features of the above embodiments can be combined arbitrarily. In order to render the description concise, all possible combinations of each technical feature in the above embodiments have not been described. However, as long as there is no contradiction in the combination of these technical features, they should be considered within the scope of the present disclosure.

Of course, the creation of the present disclosure is not limited to the aforementioned embodiments. Technicians familiar with this field can also make equivalent modifications or substitutions without violating the spirit of the present disclosure. These equivalent modifications or substitutions are all within the scope of the claims of the present disclosure.

What is claimed is:

1. An inverted LED filament, comprising:
a circuit board (200) provided with a conductive layer (210) thereon;
multiple inverted LED light emitting elements (310), wherein the circuit board (200) is provided with a strip-shaped portion (201), the inverted LED light emitting elements (310) are arranged on the strip-shaped portion (201), and the inverted LED light emitting elements (310) are all electrically connected to the conductive layer (210);
a pad assembly (220) provided on the circuit board (200) and located at the same side end of the strip-shaped portion (201), wherein, the pad assembly (220) is electrically connected to the conductive layer (210), and the pad assembly (220) can be connected to an external pin (600).

2. The inverted LED filament according to claim 1, wherein a first electrode (311) and a second electrode (312) are provided on the same side wall of the inverted LED light emitting elements (310), and the conductive layer (210) comprises at least two circuit parts (211) with a gap between the circuit parts (211), and the first electrode (311) and the second electrode (312) are respectively connected to two different circuit parts (211).

3. The inverted LED filament according to claim 1, further comprising:
a fluorescent adhesive layer (400) provided on the circuit board (200), wherein the fluorescent adhesive layer (400) surrounds the strip-shaped portion (201) and is covered on the inverted LED light emitting elements (310).

4. The inverted LED filament according to claim 1, further comprising:
a protective element (500) provided on the circuit board (200) and surrounding a connection position of the pad assembly (220) and the external pin (600).

5. The inverted LED filament according to claim 1, wherein
the circuit board (200) is made of a transparent material.

6. The inverted LED filament according to claim 1, further comprising:
a rectification unit (700) provided on the circuit board (200), the multiple inverted LED light emitting elements (310) are connected in series, parallel, or series parallel to form a light emitting circuit (300), an input end of the rectification unit (700) is electrically connected to the pad assembly (220) through the conductive layer (210), and an output end of the rectification unit (700) is electrically connected to the light emitting circuit (300) through the conductive layer (210).

7. The inverted LED filament according to claim 6, wherein the rectification unit (700) comprises a bridge rectifier, an input end of the bridge rectifier is electrically connected to the pad assembly (220), and an output end of the bridge rectifier is electrically connected to the light emitting circuit (300).

8. The inverted LED filament according to claim 1, wherein at least two strip-shaped portions (201) are provided on the circuit board (200).

9. A LED light bulb, comprising the inverted LED filament, the pin (600) according to claim 1, a connection base (800), and a light transmission cover (900), the pad assembly (220) is connected to the connection base (800) through the pin (600), and the light transmission cover (900) is connected to the connection base (800) to form a protective chamber accommodating the inverted LED filament, and the connection base (800) can be connected to an external lamp holder.

10. The LED light bulb according to claim 9, wherein a threaded part (801) is provided on the connection base (800) for connecting with the external lamp holder.
